(19) United States
(12) Patent Application Publication
(10) Pub. No.: US 2008/0299722 A1
(43) Pub. Date: Dec. 4, 2008

(54) Manufacturing method for forming a recessed channel transistor, method for forming a corresponding integrated semiconductor memory device and corresponding self-aligned mask structure

(76) Inventors: Jessica Hartwich, Dresden (DE); Andrew Graham, Dresden (DE); Arnd Scholz, Dresden (DE); Yimin Wang, Dresden (DE); Stefan Slesazeck, Dresden (DE); Lars Heineck, Dresden (DE); Franz Hofmann, Munchen (DE)

Correspondence Address: FAY KAPLUN & MARCIN, LLP, 150 BROADWAY, SUITE 702, NEW YORK, NY, 10038, US

(21) Appl. No.: 11/807,550

(22) Filed: May 29, 2007

(51) Int. Cl. H01L 21/8242

(52) U.S. Cl. 438/243; 430/5; 257/E21.646

(57) ABSTRACT

The present invention provides a method for forming a recessed channel transistor comprising the steps of:
forming a plurality of active areas lines in a semiconductor substrate with an upper surface, said lines being segmented by segmentation structures having an upper surface height differing from the substrate surface;
forming a first and a second extension region arranged above the active area and adjacent said segmentation structures;
forming recessed channel devices in the active area segments in the remaining portion of the active area segment between said extension regions.

### BACKGROUND OF THE INVENTION

1. Field of the Invention

The present invention relates to a method for forming a recessed channel transistor, a manufacturing method for forming a corresponding integrated semiconductor memory device, and to a corresponding self-aligned mask structure.

2. Description of the Related Art

Although in principle applicable to arbitrary integrated semiconductor memory devices, the following invention and the underlying problems will be explained with respect to integrated DRAM memory circuits in silicon technology, in particular, DRAM technology which is scaled down to below 100 nm generation and provides big challenges.

DRAM memory circuits of today usually comprise stripe-like active areas, e.g. fabricated in silicon, separated by STI insulation trenches filled with a dielectric material such as silicon oxide.

In trench capacitor DRAM memory circuits, along said stripe-like active areas, memory cell trench capacitors are arranged which are separated from each other by intervening memory cell transistor forming regions where the respective memory cell transistors are formed.

With feature sizes that are becoming smaller and smaller and nowadays are well below 100 nm, it becomes a challenging task to form mask openings for etching grooves for EUD (Extended U-Groove Device) transistors into the active area stripes between the memory cell capacitors in a manner which is reliable and reproducible in mass production.

### BRIEF SUMMARY OF THE INVENTION

According to a first aspect of the invention, a method for forming a recessed channel transistor as claimed in claim 1 is provided.

According to a second aspect of the invention, a method for forming a recessed channel transistor as claimed in claim 11 is provided.

According to a third aspect of the invention, a manufacturing method for an integrated semiconductor memory device as claimed in claim 12 is provided.

According to a fifth aspect of the invention, a manufacturing method for an integrated semiconductor memory device as claimed in claim 27 is provided.

According to a sixth aspect of the invention, a manufacturing method for an integrated semiconductor memory device as claimed in claim 31 is provided.

According to a seventh aspect of the invention, a self-aligned mask structure for manufacturing an integrated semiconductor memory device as claimed in claim 37 is provided.

Further embodiments are listed in the respective dependent claims.

### DESCRIPTION OF THE DRAWINGS

In the Figures:

FIG. 1A-J show schematic layouts for illustrating a manufacturing method for a recessed channel transistor in an integrated semiconductor memory device according to a first embodiment of the present invention, namely a) as plain view, b) as cross-section along line A-B of a), and c) as cross-section along line C-D of a);

FIG. 2A-D show schematic layouts for illustrating a manufacturing method for a recessed channel transistor in an integrated semiconductor memory device according to a second embodiment of the present invention, namely a) as plain view, b) as cross-section along line A-B of a), and c) as cross-section along line C-D of a);

FIG. 3A-D show schematic layouts for illustrating a manufacturing method for a recessed channel transistor in an integrated semiconductor memory device according to a third embodiment of the present invention, namely a) as plain view, b) as cross-section along line A-B of a), and c) as cross-section along line C-D of a);

FIG. 4A-D show schematic layouts for illustrating a manufacturing method for a recessed channel transistor in an integrated semiconductor memory device according to a fourth embodiment of the present invention, namely a) as plain view, b) as cross-section along line A-B of a), and c) as cross-section along line C-D of a);

FIG. 5A-D show schematic layouts for illustrating a manufacturing method for a recessed channel transistor in an integrated semiconductor memory device according to a fifth embodiment of the present invention, namely a) as plain view, b) as cross-section along line A-B of a), and c) as cross-section along line C-D of a);

FIG. 6A,B show schematic layouts for illustrating a manufacturing method for a recessed channel transistor in an integrated semiconductor memory device according to a sixth embodiment of the present invention, namely a) as plain view, b) as cross-section along line A-B of a), and c) as cross-section along line C-D of a); and

FIG. 7A-D show schematic layouts for illustrating a manufacturing method for a recessed channel transistor in an integrated semiconductor memory device according to a seventh embodiment of the present invention, namely a) as plain view, b) as cross-section along line A-B of a), and c) as cross-section along line C-D of a).

In the Figures, identical reference signs denote equivalent or functionally equivalent components.

### DESCRIPTION OF THE PREFERRED EMBODIMENTS

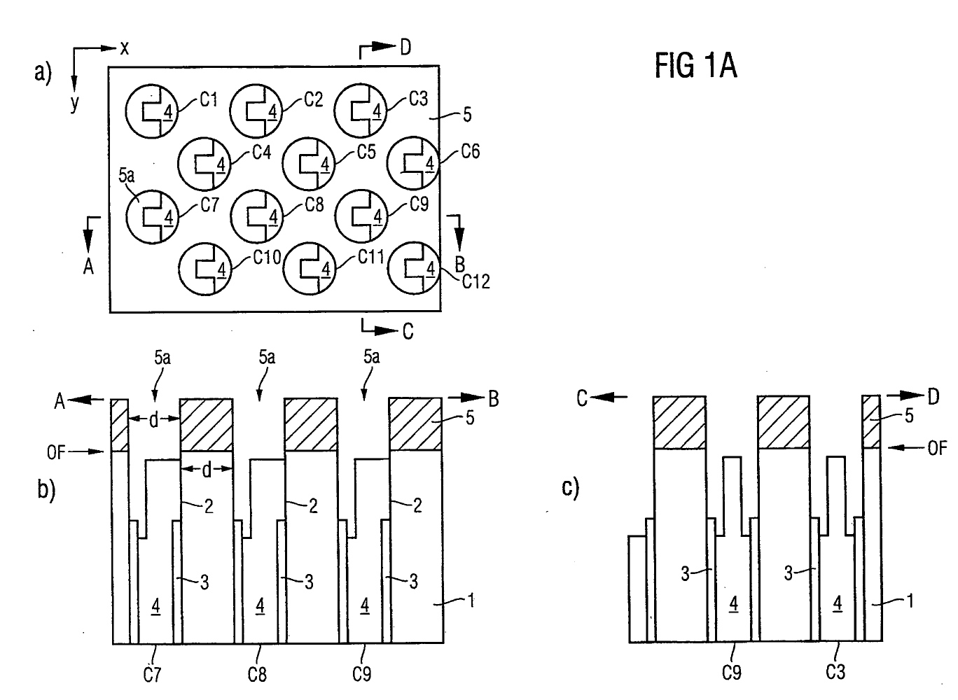

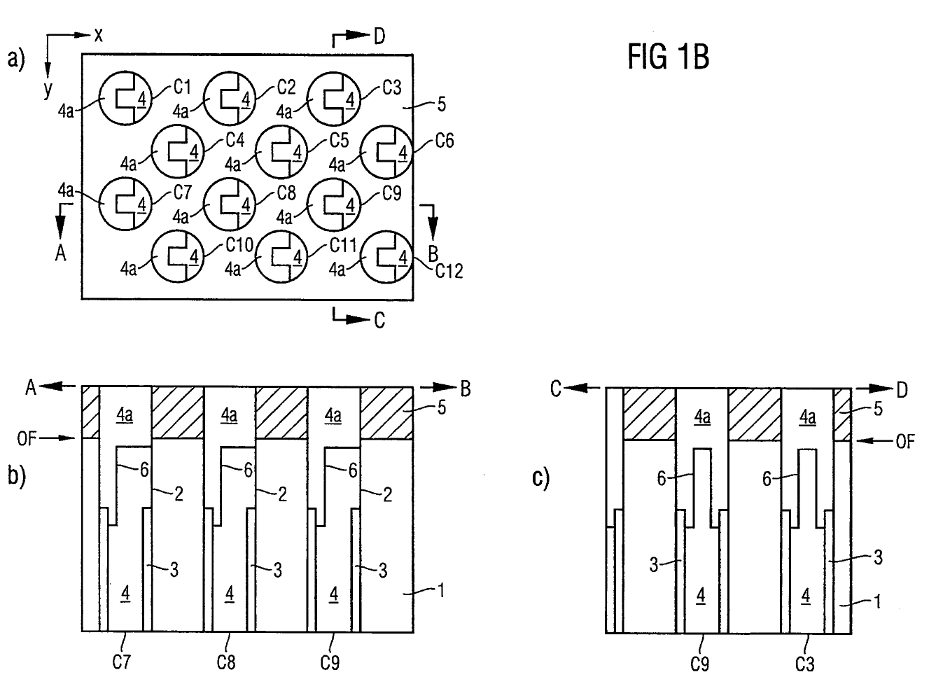

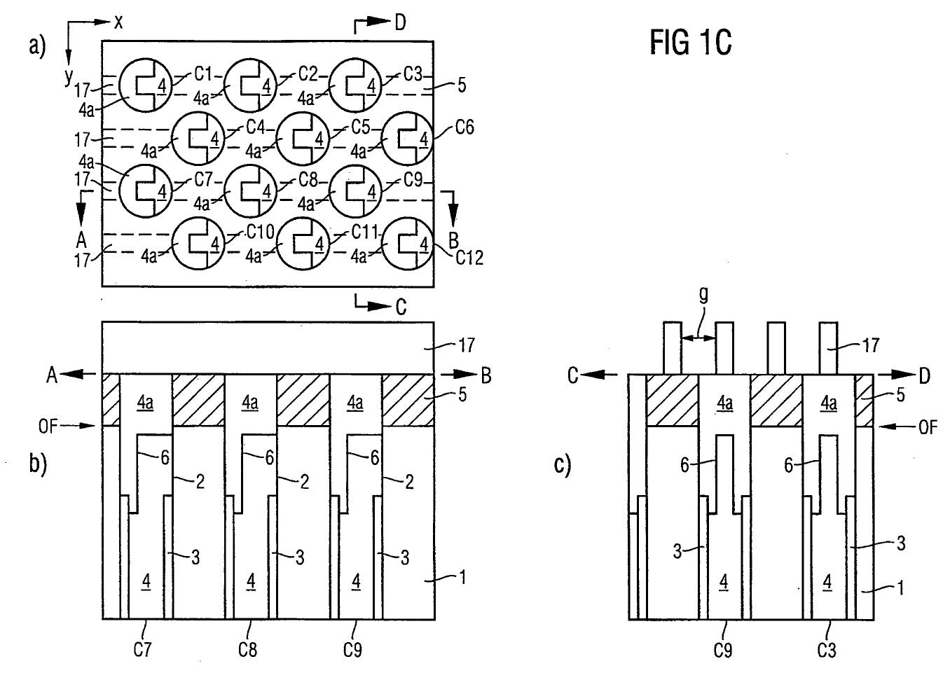

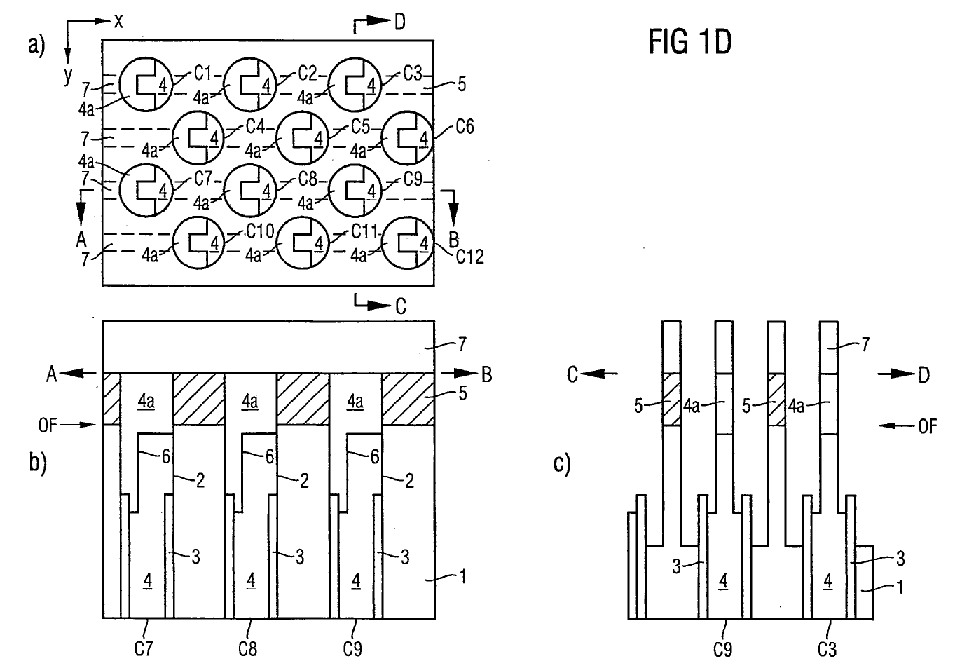

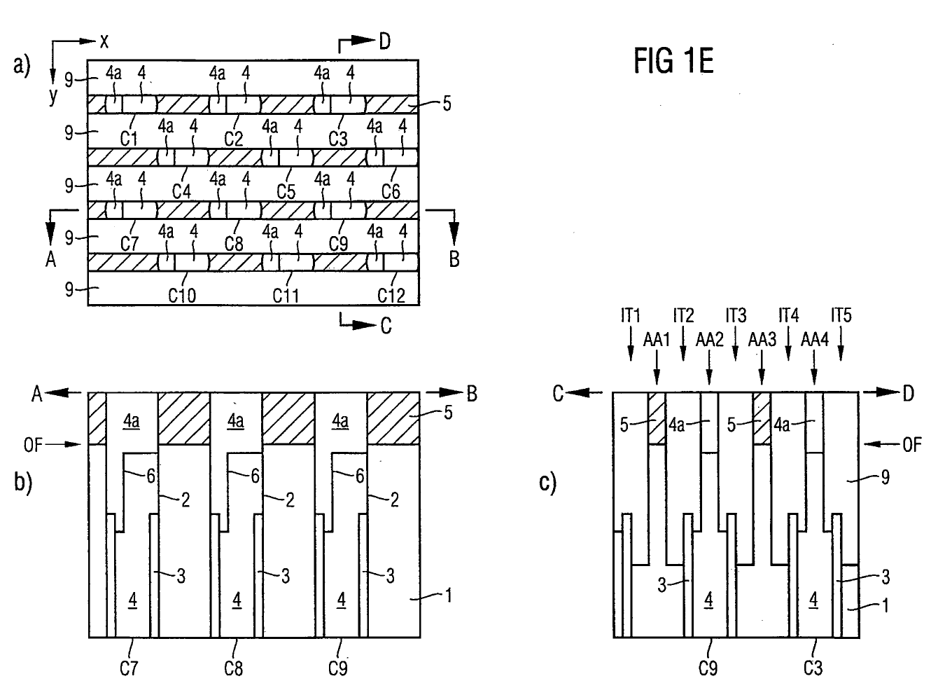

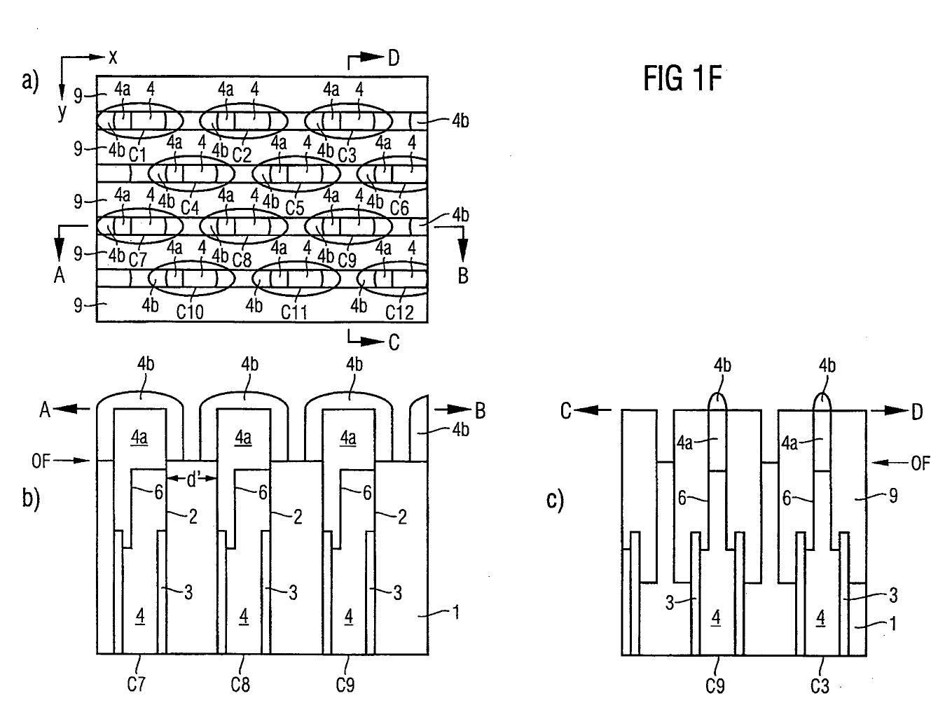

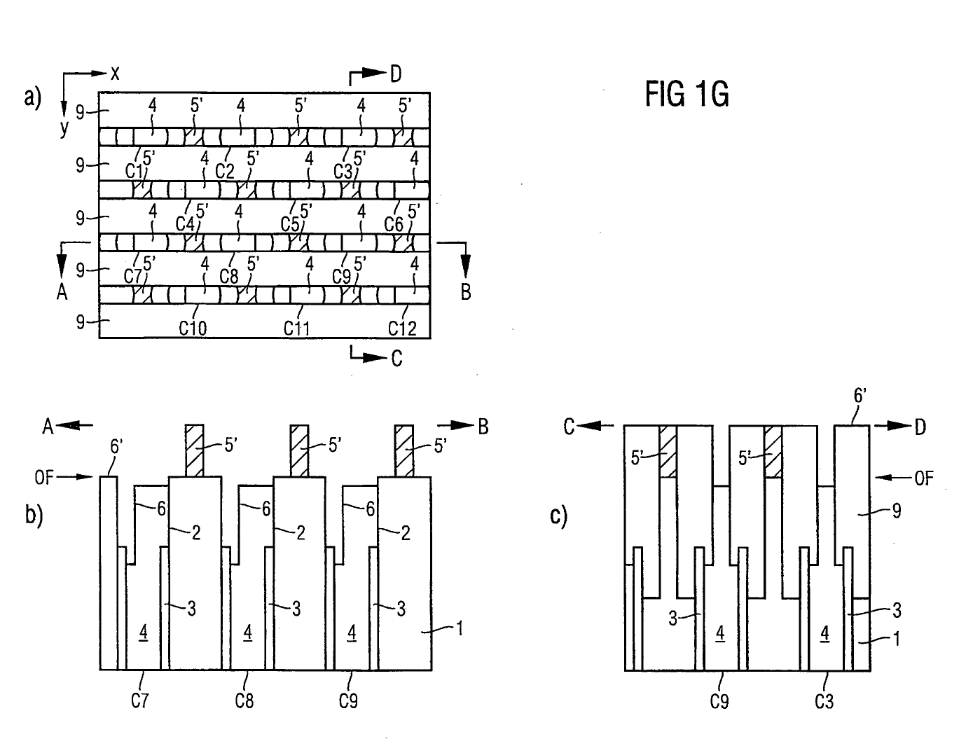

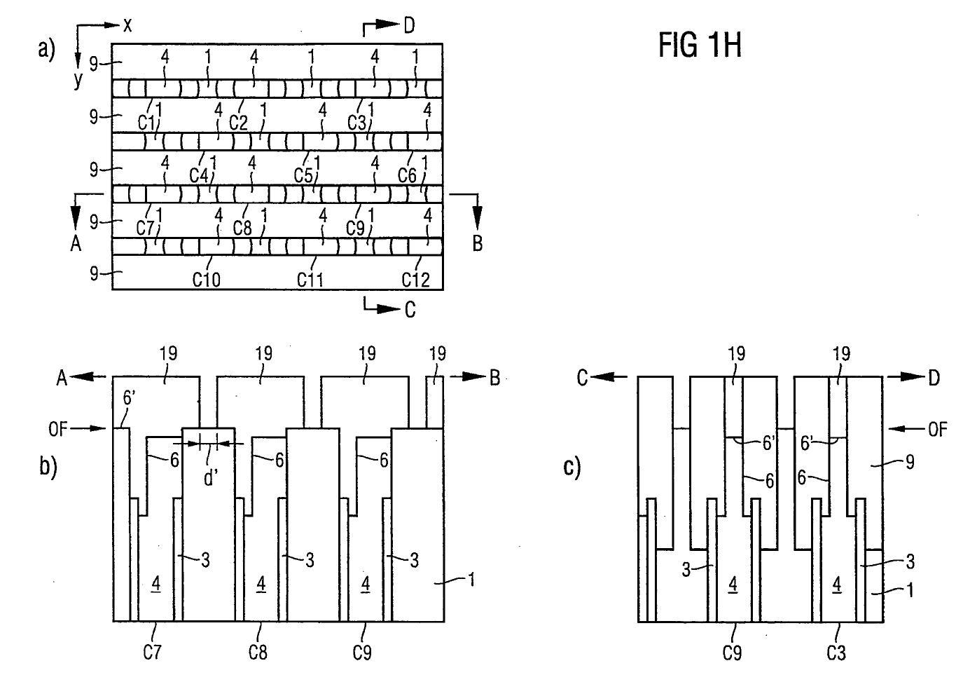

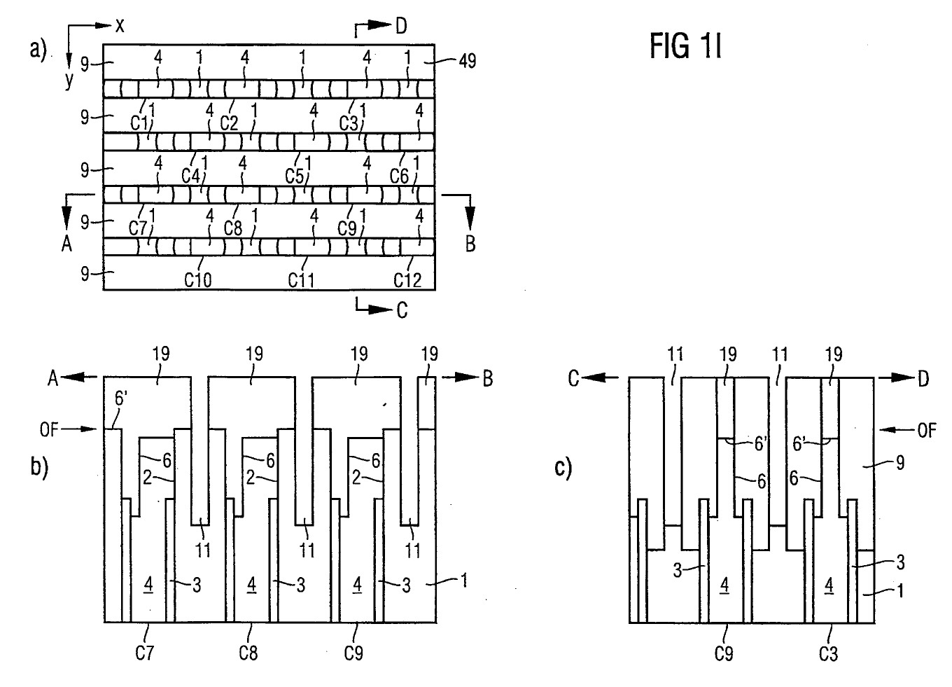

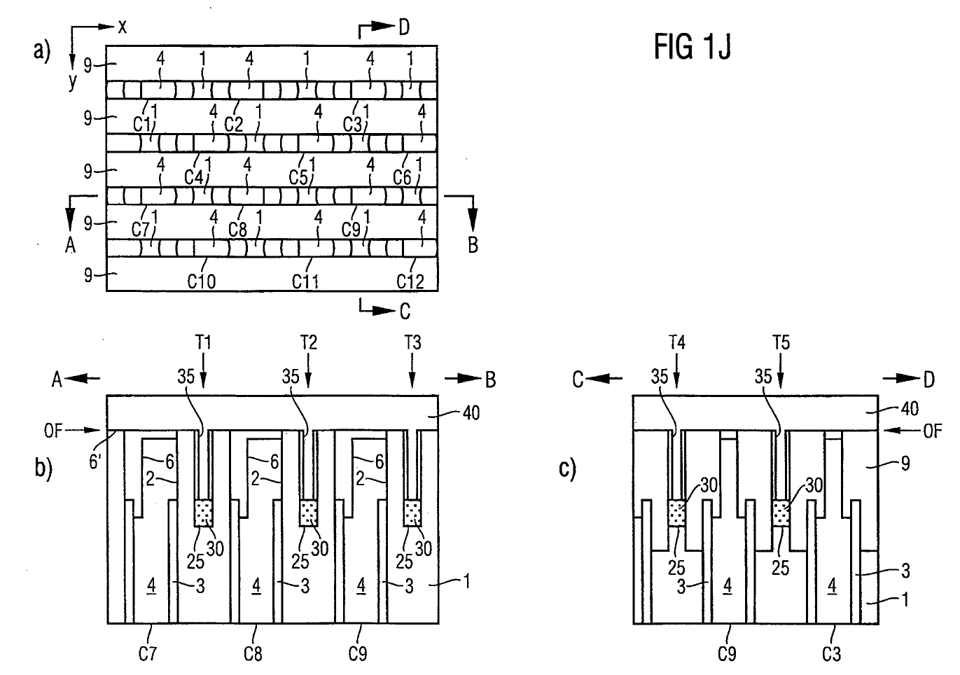

FIG. 1A-J show schematic layouts for illustrating a manufacturing method for a recessed channel transistor in an integrated semiconductor memory device according to a first embodiment of the present invention, namely a) as plain view, b) as cross-section along line A-B of a), and c) as cross-section along line C-D of a).

In FIG. 1A, reference sign 1 denotes a silicon semiconductor substrate. Formed in said semiconductor substrate 1 is a plurality of memory cell trench capacitors C1-C12 along rows running in x-direction and along columns running in y-direction.

Said memory cell trench capacitors C1-C12 comprise in their upper regions an insulating collar 3 made of silicon oxide and an inner conductive electrode 4 made of polysilicon. The inner conductive electrodes 4 include a single-sided buried strap 2 for electrical connection to a memory cell transistor to be formed in memory cell transistor forming regions located between two adjacent memory cell trench capacitors. The diameter of the memory cell trench capacitors and the width of the intervening memory cell transistor forming regions in the substrate 1 equals d which in this example is the smallest feature size of the involved technology.

The plurality of memory cell trench capacitors C1-C12 has been formed using a first mask 5 made of silicon nitride provided on the upper surface OF of the substrate 1. The mask 5 includes openings 5a corresponding to the diameter d of said memory cell trench capacitors C1-C12.

The process state shown in FIG. 1A is the state immediately after selectively etching back a part of the inner conductive electrodes 4 in order to form said single-sided buried straps 2.

In a next process step which is illustrated in FIG. 1B, a silicon nitride liner 6 is deposited over the entire structure of FIG. 1A. Thereafter, a polysilicon layer is deposited over the nitride liner 6 and polished back in a chemical-mechanical polishing process such that it has the same upper level as the silicon nitride mask layer 5. Thus, the mask openings 5a are now filled with respective polysilicon infills 4a.

In a subsequent process step which is illustrated in FIG. 1C a silicon oxide hard mask 17 is deposited and patterned over the structure of FIG. 1B such that it has a plurality of stripes running in parallel along the x-direction and being separated from each other by a predetermined distance g which determines the width of insulation trenches to be formed in this process step.

Using said hard mask 17, first a nitride etch step and thereafter a silicon etch step are performed in order to define active area stripes and intervening insulation trenches running along the x-direction. FIG. 1D shows the process state immediately after the silicon etch step for the insulation trenches.

As depicted in FIG. 1E, the hard mask 17 is removed after the silicon etch step, and an oxide fill 9 is deposited such that it is planar with the upper surface of the nitride mask 5. Alternatively, the silicon oxide fill 9 could be deposited and polished back thereafter.

Now, the active area stripes AA1-AA4 and the intervening insulation trenches IT1-IT5 running along the x-direction are completed.

Thereafter, as shown in FIG. 1, the silicon nitride mask 5 is selectively removed in a nitride etch step. Then, spacers 4b made of polysilicon are formed around said remaining infills 4a which after the removal of the mask 5 protrude from the upper surface OF of the silicon semiconductor substrate 1. The spacers 4b are formed in a selective silicon epitaxial growth process which has the effect that they extend also in the height direction.

Thus, the spacers 4b laterally extend to beyond the trench openings defined by mask openings 5a and expose only a part of the memory cell transistor forming regions of a predetermined width d′. These exposed parts will later correspond to a region where respective grooves for the memory cell transistors are to be formed.

Generally, the formation of the grooves could also be performed in an immediately succeeding process step, however, in this first embodiment, the spacers 4b and infills 4a will be removed first in an intervening process step sequence.

As shown in FIG. 1G, another nitride mask 5′ is formed in the exposed parts of the memory cell transistor forming regions between the spacers 4b shown in FIG. 1F. This may easily be achieved by a nitride deposition and etch back or polish back process sequence. Thereafter, the polysilicon spacers 4b and infills 4a are removed in a selective silicon etch step. Then, another nitride liner 6′ is deposited over the entire structure which leads to the process state shown in FIG. 1G.

Thereafter, as shown in FIG. 1H an oxide fill 19 is provided which extends to the same upper level as the second nitride mask 5′. Thereafter, the second nitride mask 5′ is removed in a selective etch step.

The oxide fill 19 now forms a plurality of extension regions located above each of the plurality of memory cell trench capacitors C1-C12 on said surface OF which extension regions 19 expose said already above-mentioned part of said memory cell transistor forming regions of width d′ where the grooves of the EUD devices have to be formed.

In a next process step, which is shown in FIG. 11 said grooves 11 are formed in said memory cell transistor forming regions in a silicon etch step using said extension regions formed of oxide fill 19 as a mask.

As shown in FIG. 1J, a plurality of memory cell transistors T1-T4 is formed in said grooves 11 subsequently. Although not shown here, also an isotropic silicon etch step for widening said grooves 11 and an oxide etch step for corner device formation could be performed at this process state.

According to the shown first embodiment, a gate oxide layer 25 is formed in said grooves 11, then a polysilicon control electrode 25 is formed in the lower part of the grooves 11, then sidewall spacers 35 made of an insulating material such as silicon oxide are formed in the upper part of the grooves 11 on top of said polysilicon control electrode 25, and finally, a polysilicon contact layer 40 is deposited over the entire structure which leads to the process state shown in FIG. 1J.

As becomes immediately clear to the average skilled person, because well known in the art, the following process steps which are not illustrated here include the formation of word-lines by patterning the polysilicon contact layer 40 and the formation of bit-line contacts and bit-lines which are connected to the drains of the memory cell transistors T1-T5, the sources of which are connected to the memory cell capacitors C1-C12.

The first embodiment explained above provides a process sequence which allows the processing of the extended U-groove memory transistor devices in a self-adjusted manner with respect to the positions of the adjacent pairs of deep trench capacitors.

According to a not separately illustrated modification of the above described first embodiment, the polysilicon infills 4a are removed in the process state of FIG. 1E and replaced by corresponding carbon infills. Thereafter, the silicon nitride mask 5 is selectively removed in a nitride etch step. Then, spacers carbon made of carbon are formed around the remaining carbon infills which after the removal of the mask 5 protrude from the upper surface OF of the silicon semiconductor substrate 1.

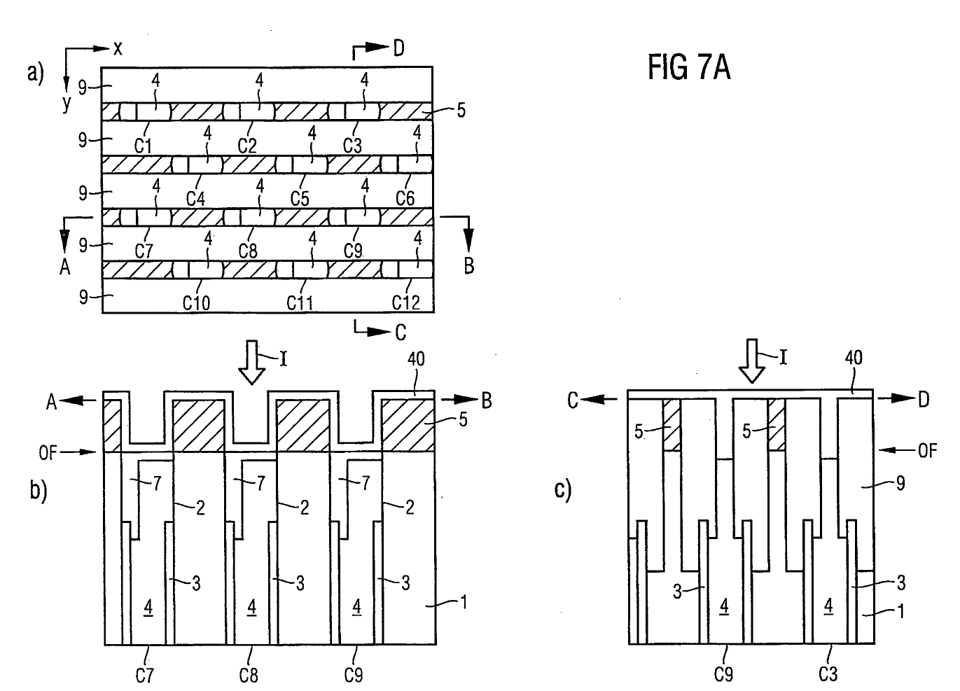

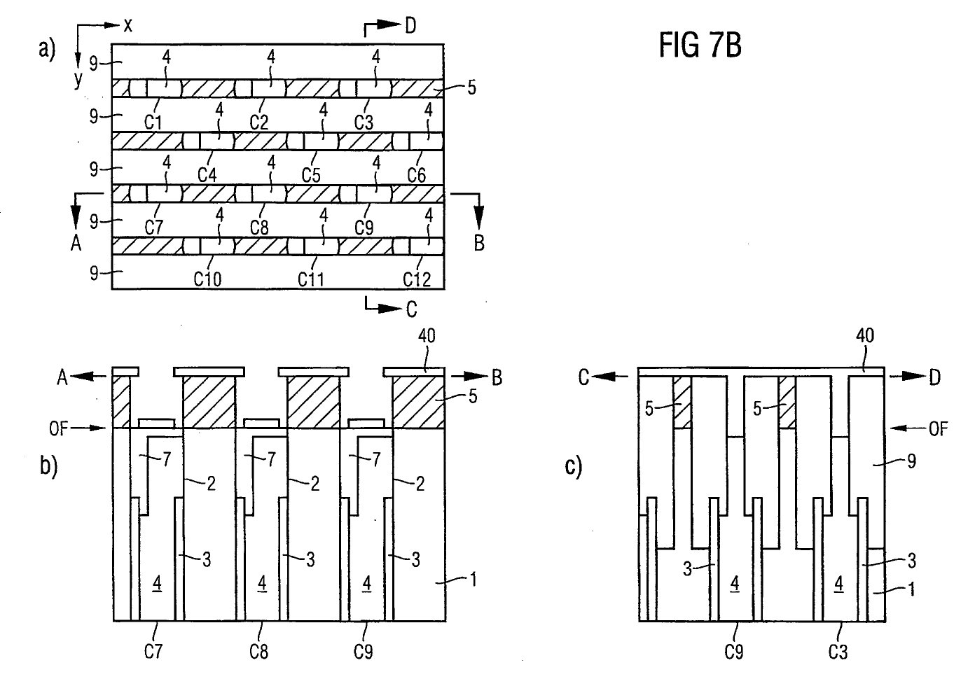

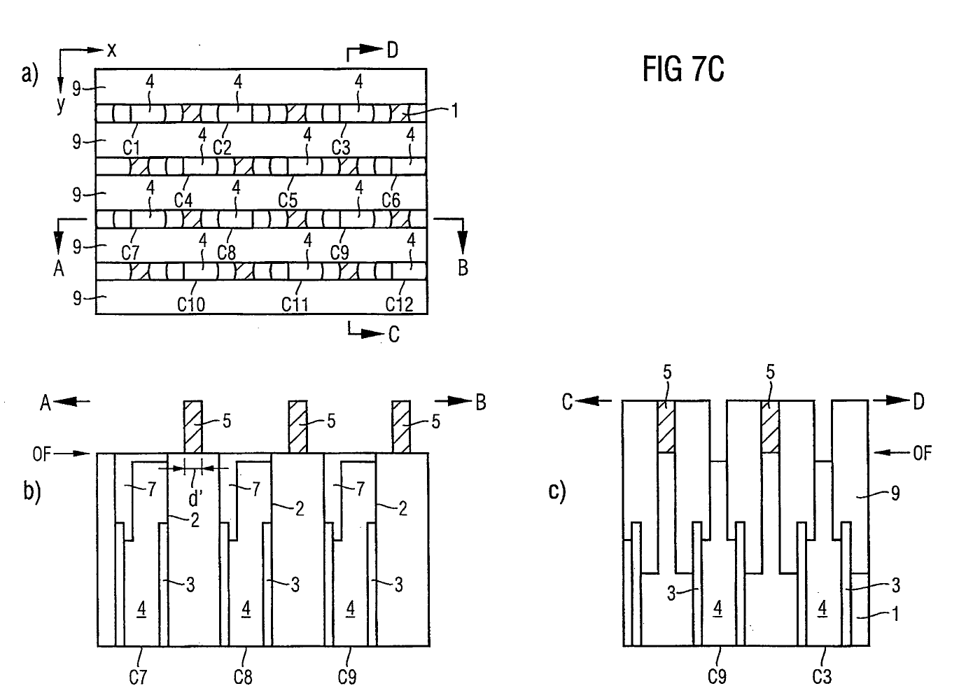

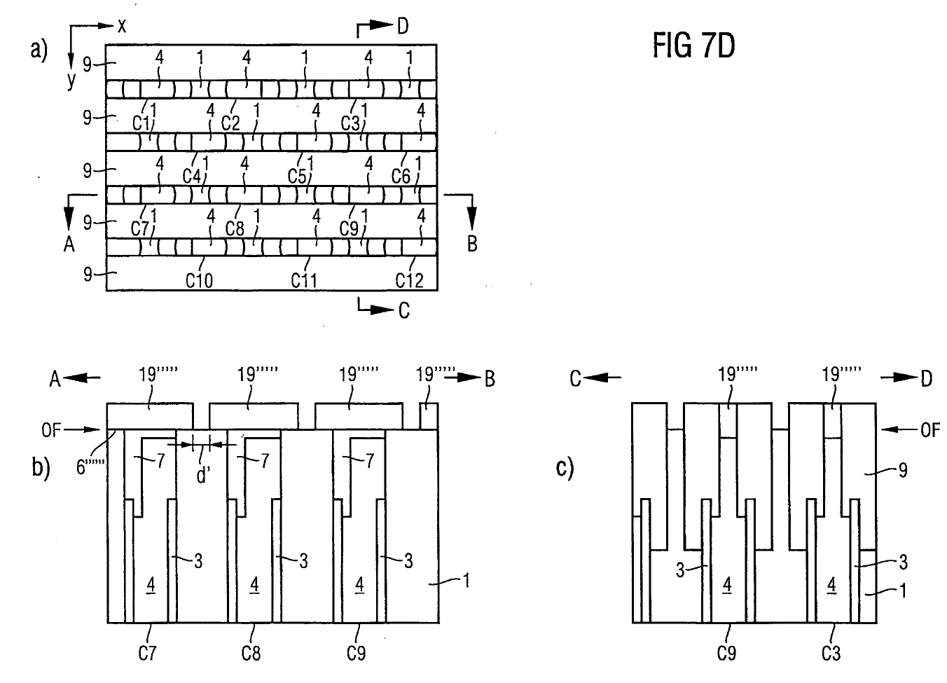

Also, the modification could start in a process state where the polysilicon infills are provided above the surface OF, said trenches being filled with an insulating fill which extends up to the upper surface OF of the substrate 1 and partially surrounds the buried strap (cmp. FIG. 7A described below).

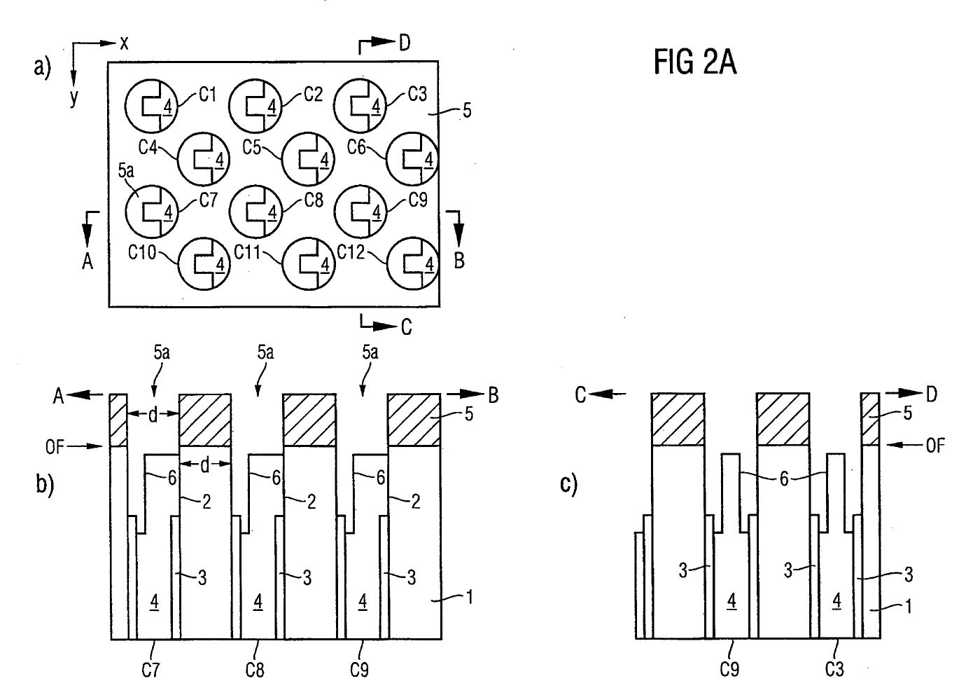

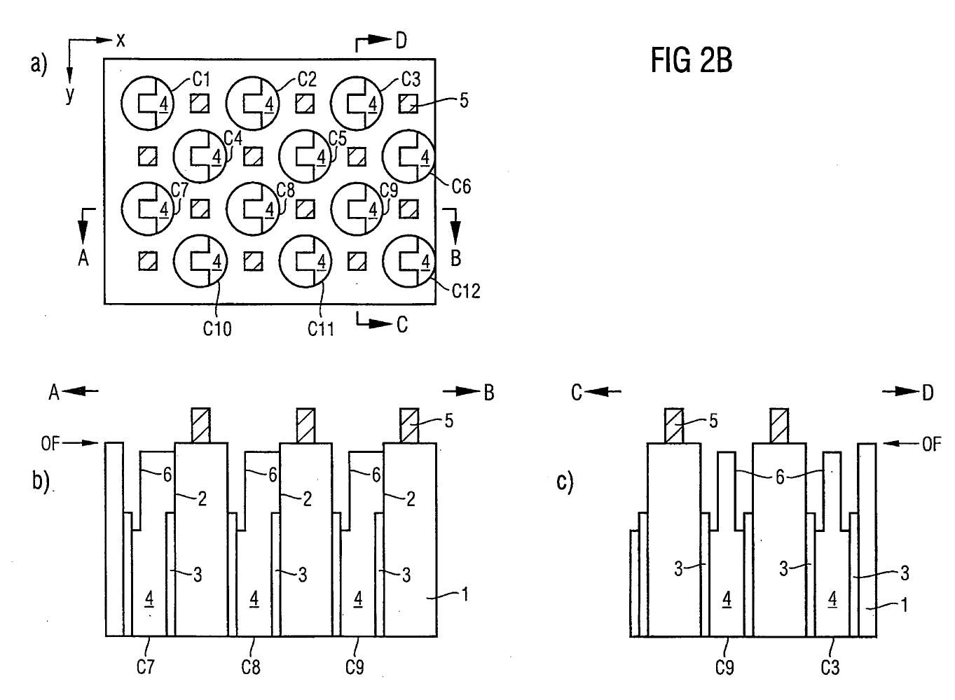

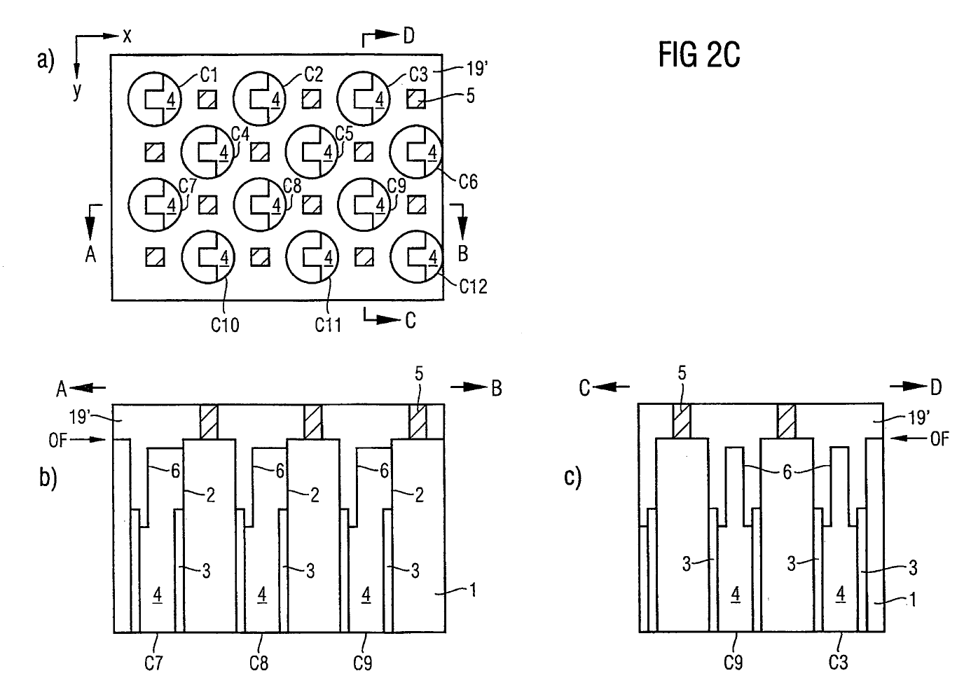

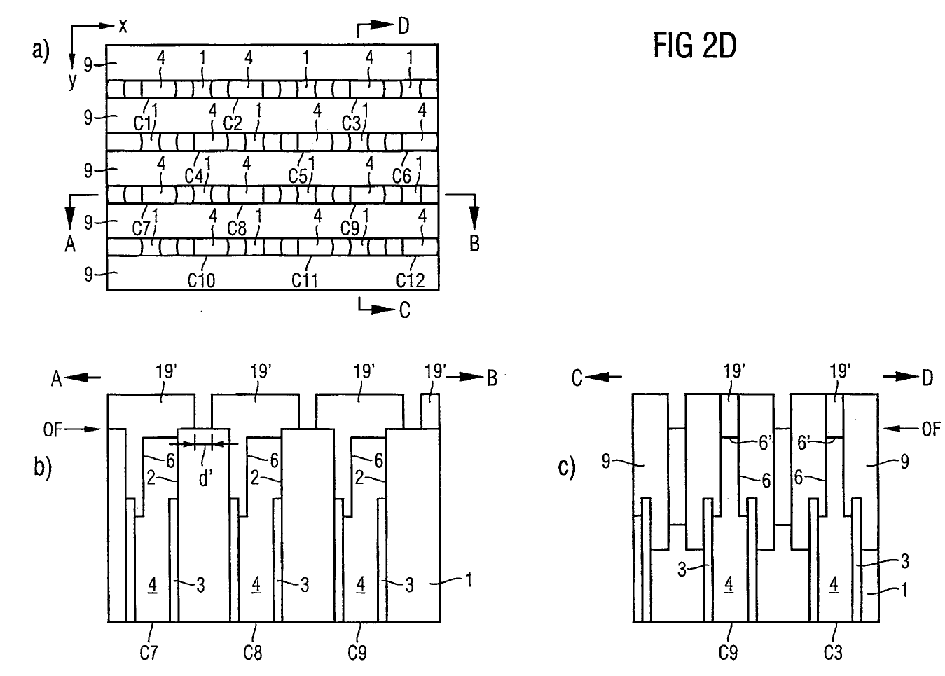

FIG. 2A-D show schematic layouts for illustrating a manufacturing method for a recessed channel transistor in an integrated semiconductor memory device according to a second embodiment of the present invention, namely a) as plain view, b) as cross-section along line A-B of a), and c) as cross-section along line C-D of a).

The process state shown in FIG. 2A is obtained from the process state of FIG. 1A by depositing said nitride liner 6 over the entire structure of FIG. 1A.

In a next process step which is shown in FIG. 2B, a nitride pullback etch step is performed in order to isotropically remove a part of the nitride mask 5 from the upper surface OF of the substrate 1.

Thereafter, as shown in FIG. 2C, an insulating oxide fill 19′ is deposited which insulating fill 19′ extends to the same height as the etched back nitride mask layer 5.

Further, as may be obtained from FIG. 2D, the insulation trench IT1-IT5 forming steps as already explained with respect to FIG. 1C, 1D, 1E are performed, whereafter the remaining part of the nitride mask 5′ is removed in a selective etch step.

The oxide fill 19′ now forms a plurality of extension regions located above each of the plurality of memory cell trench capacitors C1-C12 on said surface OF which extension regions 19′ expose said already above-mentioned part of said memory cell transistor forming regions of width d′ where the grooves of the EUD devices have to be formed.

The process state shown in FIG. 2D corresponds to the process state shown in FIG. 1H, and therefore a repeated description of the remaining process steps will be omitted here.

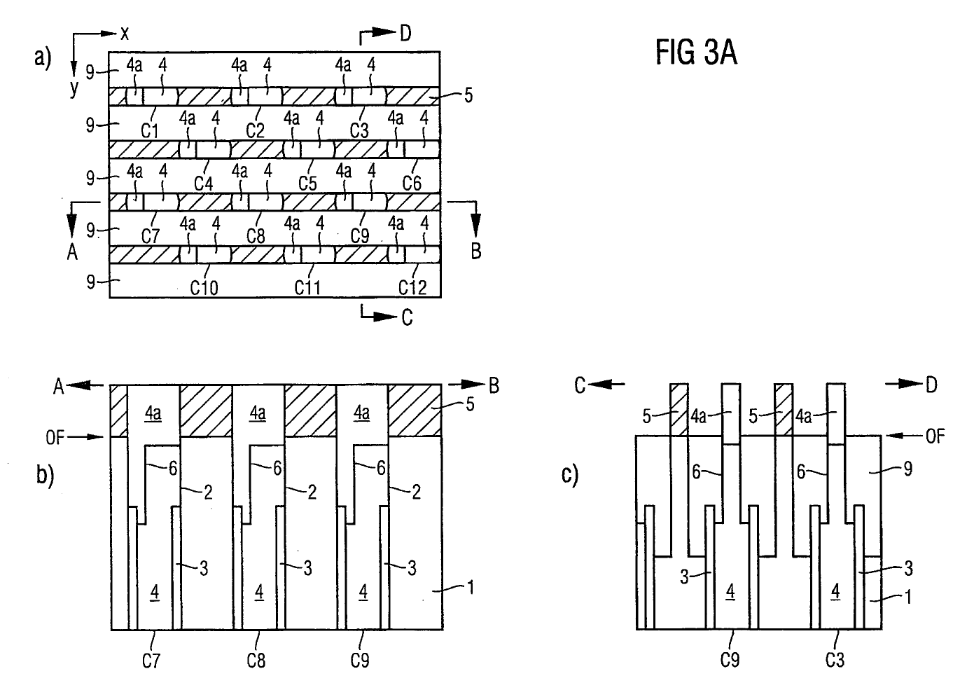

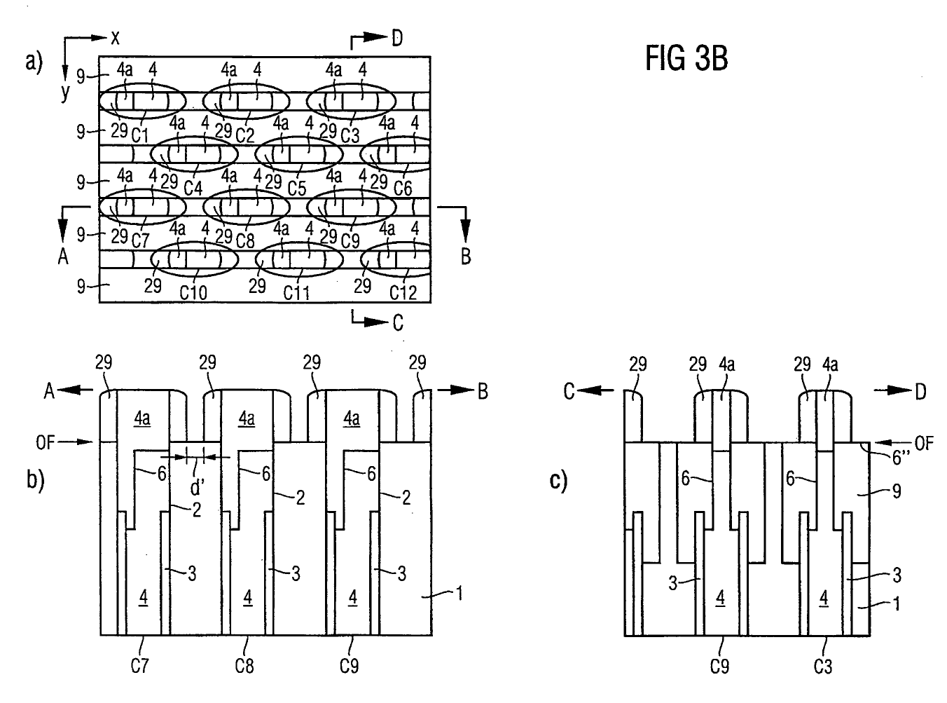

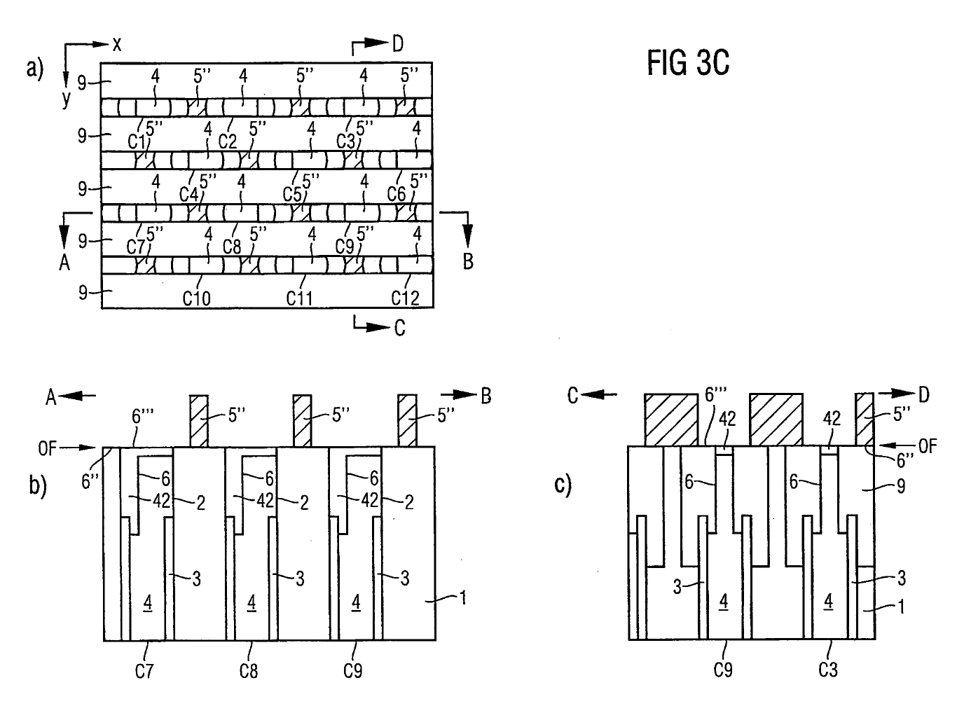

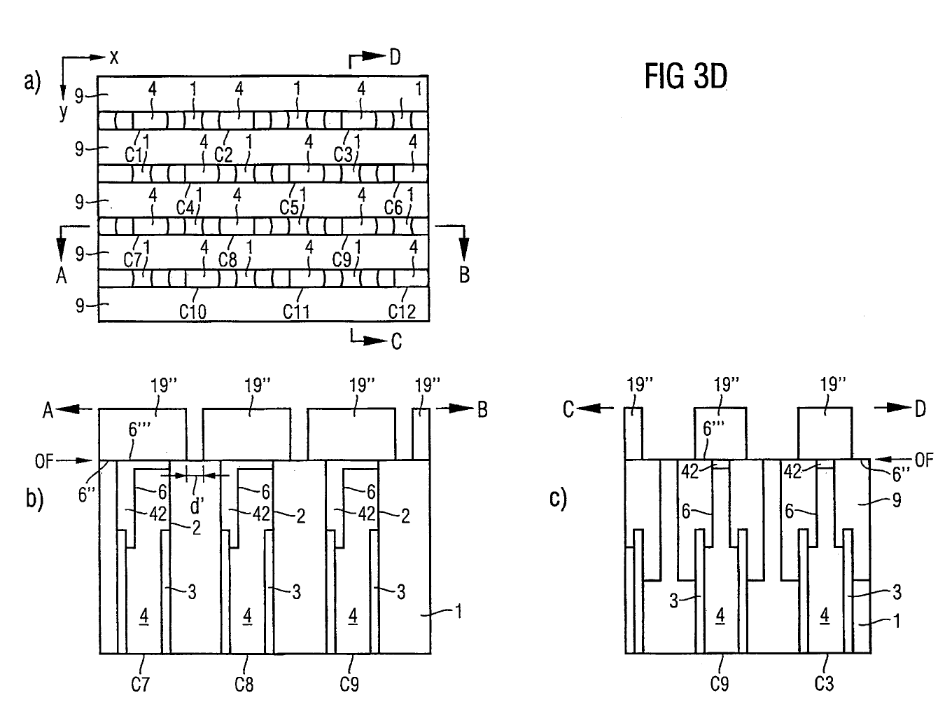

FIG. 3A-D show schematic layouts for illustrating a manufacturing method for a recessed channel transistor in an integrated semiconductor memory device according to a third embodiment of the present invention, namely a) as plain view, b) as cross-section along line A-B of a), and c) as cross-section along line C-D of a).

The process state shown in FIG. 3A originates from the process state shown in FIG. 1E after having performed a recess etch of the STI oxide fill layer 9. The depth of the recess corresponds to the height of the nitride mask layer 5.

In a subsequent process step which is shown in FIG. 3B the nitride mask 5 is removed in a selective etch step. Then, a nitride liner 6″ is deposited over the entire structure.

Subsequently, a TEOS spacer formation step is performed in order to form respective TEOS spacers 29 around the infills 4a which after the recess etch of the STI oxide fill layer 9 protrude from the upper surface OF of the substrate 1. After the spacer formation step, said part of said memory cell transistor forming regions of the predetermined width d′ is exposed.

Thereafter, as shown in FIG. 3C, a second nitride mask 5″ is formed between the spacers 29 by depositing and etching back a nitride layer. Subsequently, the polysilicon infills 4a are removed in a silicon etch step, whereafter the spacers 29 are removed in an oxide etch step.

Then, an insulating fill 42 made of silicon oxide is deposited and etched back so as to be planar with the upper surface OF of the substrate 1. In order to achieve the process state shown in FIG. 3C another nitride liner 6′″ is deposited over the entire structure. Thereafter, an oxide fill 19″ is provided which extends to the same upper level as the second nitride mask 5″.

As may be obtained from FIG. 3D, the second nitride mask 5″ is selectively removed in order to expose the part of the memory cell transistor forming region having the width d′ where the grooves for the memory cell transistor have to be formed in the following steps the explanation of which is omitted here because it has already been given with respect to FIGS. 1H-1J.

The oxide fill 19″ now forms a plurality of extension regions located above each of the plurality of memory cell trench capacitors C1-C12 on said surface OF which extension regions 19″ serve as a mask in the step of forming grooves of the EUD devices.

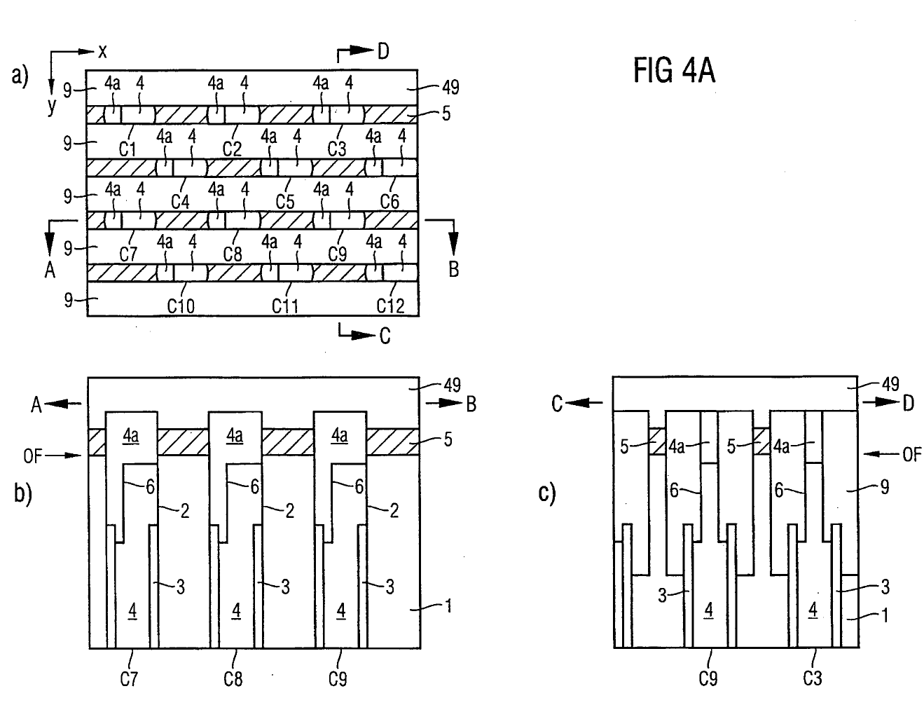

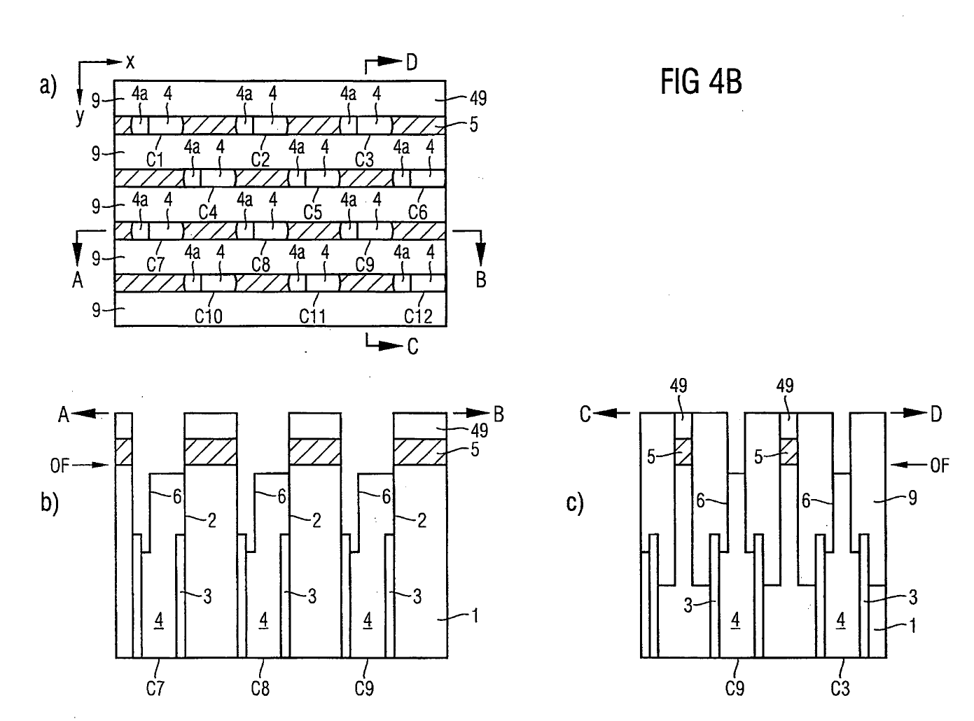

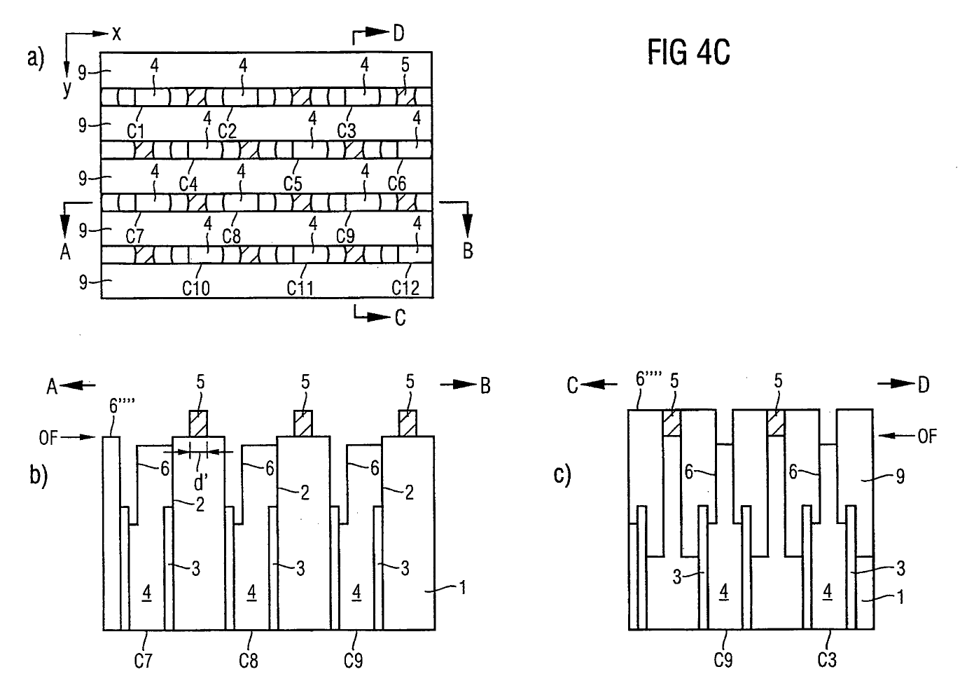

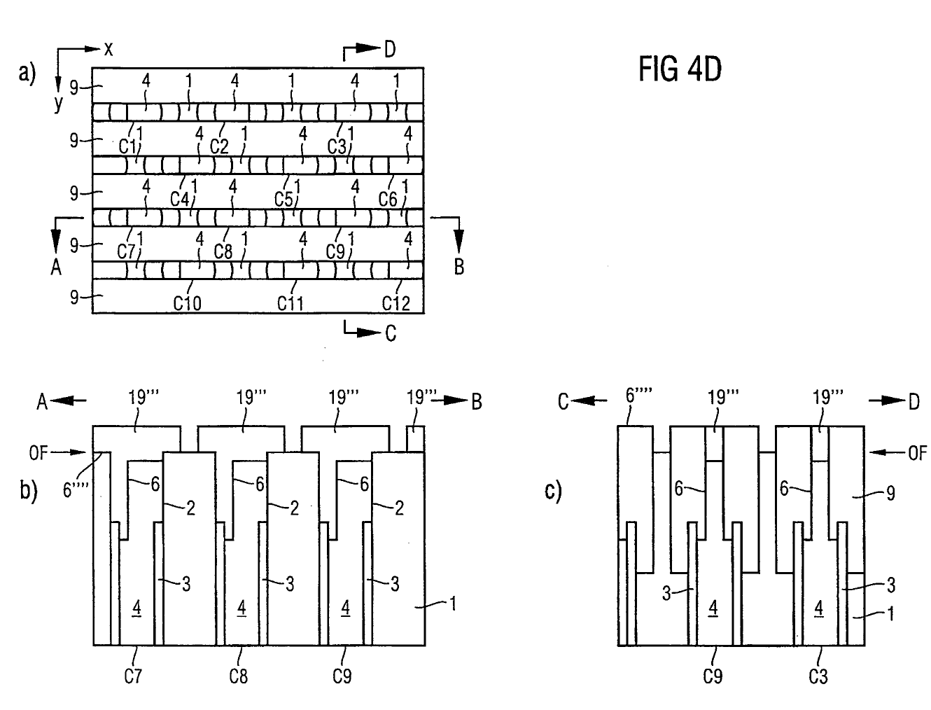

FIG. 4-D show schematic layouts for illustrating a manufacturing method for a recessed channel transistor in an integrated semiconductor memory device according to a fourth embodiment of the present invention, namely a) as plain view, b) as cross-section along line A-B of a), and c) as cross-section along line C-D of a).

The process state shown in FIG. 4A originates from the process state shown in FIG. 1E by performing a nitride recess etch step for recessing the nitride mask 5 and by performing a depositing step for depositing an oxide layer 49 over the entire structure.

Thereafter, as shown in FIG. 4B, the oxide layer 49 is recessed to the upper level of the polysilicon infills 4a. Then, a silicon etch step is performed for removing the polysilicon infills 4a, completely. Said silicon etch step stops on the nitride liner 6.

Further with reference to FIG. 4C, a nitride pullback etch step is performed under the remaining oxide layer 49 as a mask. Thereafter, the oxide layer 49 is completely removed. Finally, another nitride liner 6″″ is deposited over the entire structure which leads to the process state shown in FIG. 4C.

With reference to FIG. 4D, an oxide fill layer 19′″ is provided which extends to the same upper level as the etched back nitride mask layer 5. Then, the nitride mask layer is removed completely in a selective etch step. As to reach the process state shown in FIG. 4D which corresponds to the process step shown in FIG. 1H.

The oxide fill 19′″ now forms a plurality of extension regions located above each of the plurality of memory cell trench capacitors C1-C12 on said sur-face OF which extension regions 19′″ serve as a mask in the step of forming grooves of the EUD devices.

The remaining process steps will not be repeatedly described because this has already been done with respect to FIGS. 1I-1J above.

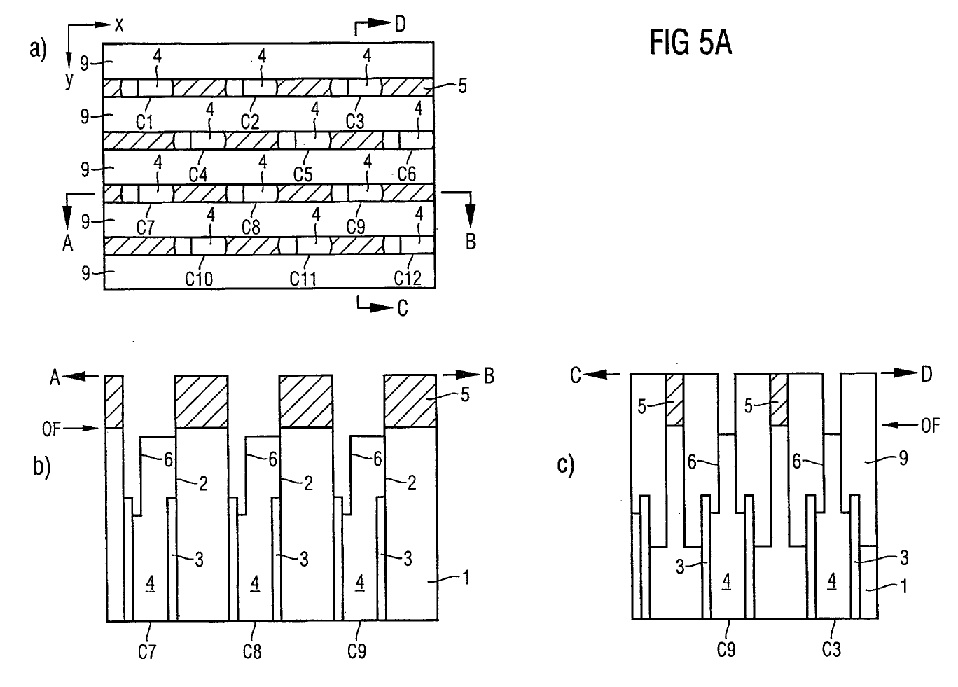

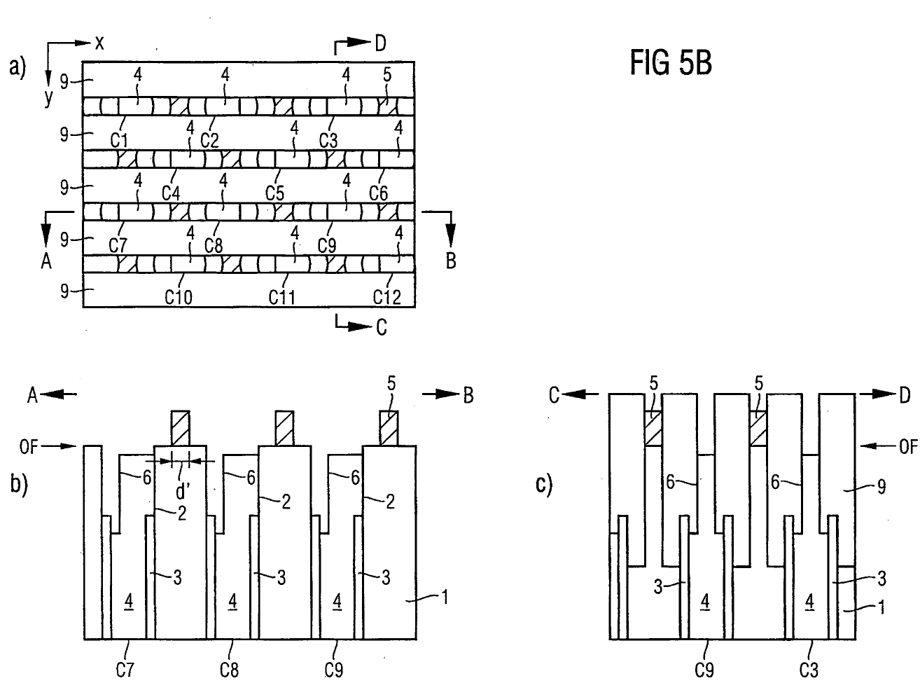

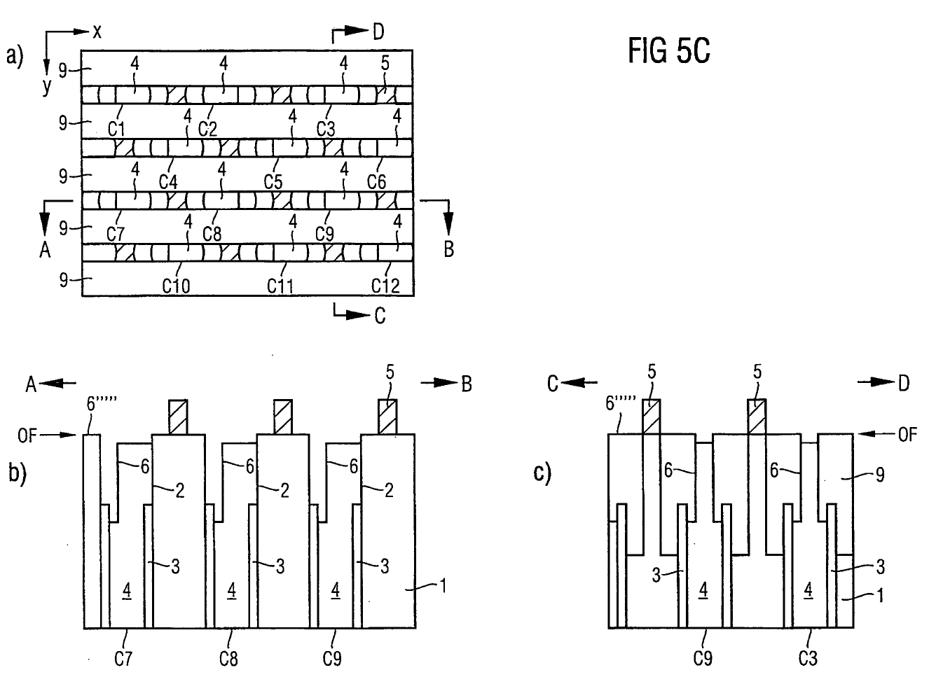

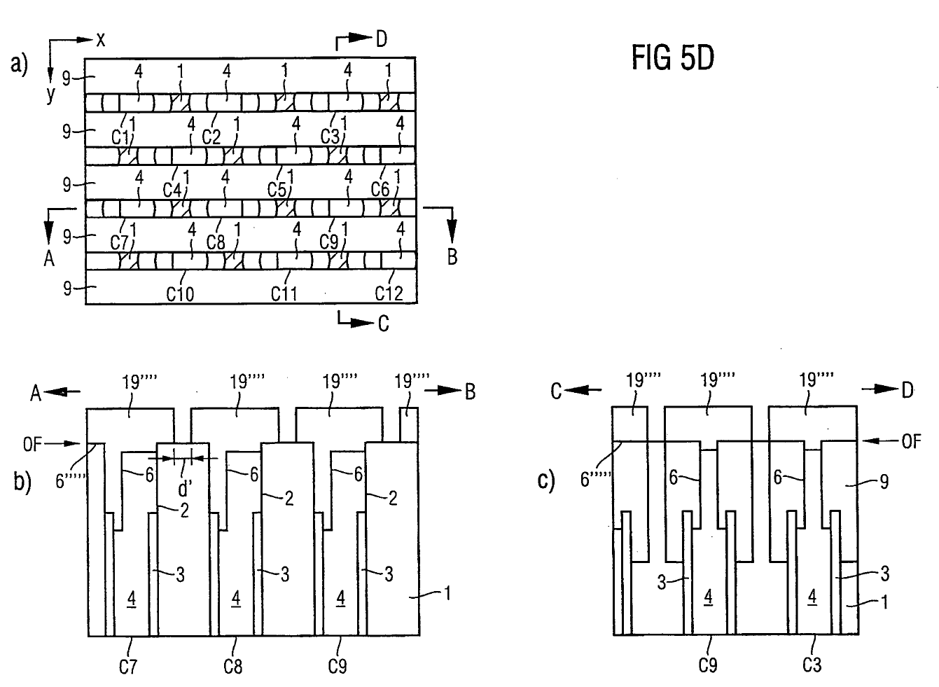

FIG. 5A-D show schematic layouts for illustrating a manufacturing method for a recessed channel transistor in an integrated semiconductor memory device according to a fifth embodiment of the present invention, namely a) as plain view, b) as cross-section along line A-B of a), and c) as cross-section along line C-D of a).

The process step shown in FIG. 5A originates from the process step shown in FIG. 1E by selectively removing the polysilicon infills 4a in a corresponding silicon etch step which stops on the nitride liner 6.

Thereafter, as shown in FIG. 5B, a nitride pullback etch step is performed for removing a part of the nitride mask 5. The remaining part of the nitride mask 5 covers the part having the width d′ of the memory cell transistor forming region between adjacent memory cell trench capacitors.

As shown in FIG. 5C, the insulation trench oxide layer 9 is then selectively recessed to the level of the upper surface OF of the substrate 1, and then another nitride liner 6″″″ is deposited over the entire structure.

Then, as shown in FIG. 5D an oxide fill layer 19″″ is provided up to the level of the nitride mask layer 5 whereafter the nitride mask layer 5 is removed in a selective etch step so as to obtain the process state shown in FIG. 5D which corresponds to the process state shown in FIG. 1H.

The oxide fill 19″″ now forms a plurality of extension regions located above each of the plurality of memory cell trench capacitors C1-C12 on said surface OF which extension regions 19″″ serve as a mask in the step of forming grooves of the EUD devices.

The remaining steps correspond to the process steps already described with respect to FIGS. 1I-1J.

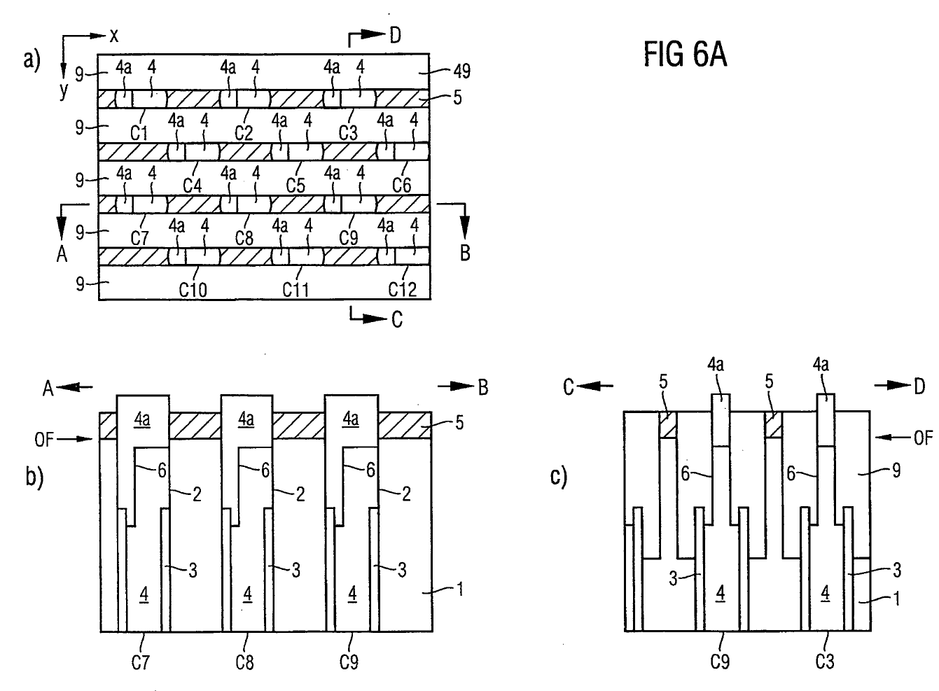

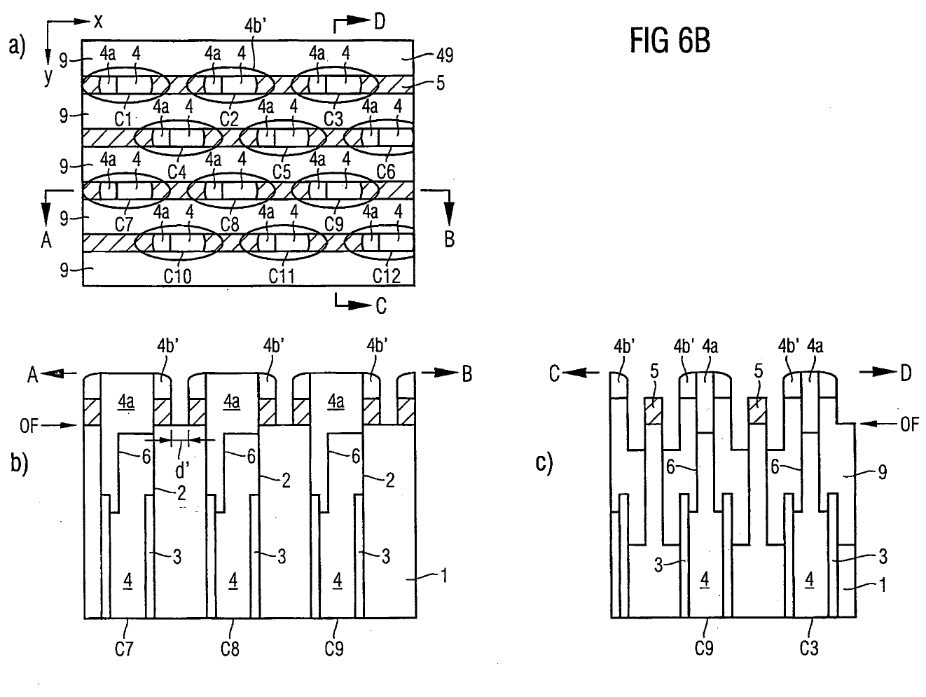

FIG. 6A,B show schematic layouts for illustrating a manufacturing method for a recessed channel transistor in an integrated semiconductor memory device according to a sixth embodiment of the present invention, namely a) as plain view, b) as cross-section along line A-B of a), and c) as cross-section along line C-D of a).

The process state shown in FIG. 6A is based on the process step shown in FIG. 1E and is obtained therefrom by recessing the insulating oxide layer 9 of the insulation trenches and by recessing the nitride mask 5 by the same height.

In a subsequent process step which is shown in FIG. 6B, polysilicon spacers 4b′ are formed around the polysilicon infills 4a which after the recess steps protrude from the surface of the nitride mask layer 5.

Thereafter, the nitride mask 5 is etched selectively using said polysilicon spacers 4b′ formed around said infills 4a as a mask in order to obtain the process state shown in FIG. 6B.

The thus obtained exposed part of the memory transistor forming region between two adjacent memory cell trench capacitors having the width d′ corresponds to the part where the groove for the memory cell transistor has to be etched using the infills 4a extended by the spacers 4b′ as a mask.

In this embodiment, the extension region is formed of the nitride mask 5, the polysilicon infills 4a, and the polysilicon spacers 4b′.

The remaining steps correspond to the process steps already described with respect to FIGS. 1I-1J.

FIG. 7A-D show schematic layouts for illustrating a manufacturing method for a recessed channel transistor in an integrated semiconductor memory device according to a seventh embodiment of the present invention, namely a) as plain view, b) as cross-section along line A-B of a), and c) as cross-section along line C-D of a).

The process state shown in FIG. 7A originates from the process state shown in FIG. 1E by selectively removing the polysilicon infills 4a and by depositing and etching back an insulating fill 7 which extends up to the upper surface OF of the substrate 1.

In a subsequent process step a polysilicon liner 40 is deposited over the entire structure and thereafter subjected to an ion implantation I which is directed perpendicular to the upper surface OF of the substrate 1, as may be obtained from FIG. 7A.

As a consequence of this implantation step, the horizontal implanted parts of the polysilicon liner 40 are much more resistant against a specific etching than the non-implanted parts along the verticals.

Consequently, it is possible to remove the vertical parts of the liner 40 along the nitride mask 5 in a selective etch step which is depicted in FIG. 7B.

Further with respect to FIG. 7C a nitride pullback etch step is performed so as to remove a part of the nitride mask 5 such that the remaining part of the nitride mask 5 corresponds to the part of the memory cell transistor forming region having width of d′ corresponding to the groove to be formed for the memory cell transistor.

Finally, with respect to FIG. 7D, another nitride liner 6″″″ is deposited over the entire structure, and thereafter an oxide fill layer 19″″″ is deposited up to the upper level of the nitride mask 5. Then, the nitride mask 5 is removed in a selective etch step so as to obtain the process state shown in FIG. 7D which corresponds to the process step shown in FIG. 1H.

The oxide fill 19′″″ now forms a plurality of extension regions located above each of the plurality of memory cell trench capacitors C1-C12 on said surface OF which extension regions 19′″″ serve as a mask in the step of forming grooves of the EUD devices.

The remaining process steps correspond to the process steps shown in FIGS. 1I, 1J already explained above.

Although the present invention has been described with reference to a preferred embodiment, it is not limited thereto, but can be modified in various manners which are obvious for a person skilled in the art. Thus, it is intended that the present invention is only limited by the scope of the claims attached herewith.

In particular, the present invention is not limited to the material combinations referred to in the above embodiments. Moreover, the invention is applicable for any kind of memory such as DRAM, SRAM, ROM, NVRAM etc.

1. A method for forming a recessed channel transistor and a recessed gate electrode, comprising the steps of:
forming a plurality of active area lines in a semiconductor substrate with an upper surface, said lines being segmented by segmentation structures having an upper surface height differing from the substrate surface height;
forming a first and a second extension region arranged above the active area and adjacent said segmentation structures; and
forming a recessed channel transistor comprising the recessed gate electrode in the active area segment between said extension regions, wherein between said extension regions a first mask is formed in the active area segment between said extension regions having mask openings corresponding to the extension region,
wherein a second mask is formed in the mask openings of the first mask,
wherein the first mask is removed after formation of the second mask, and
wherein the transistor is formed using the second mask.

2. The method according to claim 1, wherein the pair of extension regions have the same width measured in the direction of the active area lines.

3. The method according to claim 1, wherein the upper surface of the segmentation structure is arranged above the substrate surface.

4. The method according to claim 3, wherein the step of forming the extension regions comprises forming a spacer at the side walls of the segmentation structure.

5. The method according to claim 1, wherein the upper surface of the segmentation structure is arranged below the substrate surface.

6. The method according to claim 5, where in the active area is covered by a pad layer, and wherein the step of forming the extension regions comprises removing portions of the pad layer.

7. The method according to claim 6, wherein the pad layer comprises a silicon nitride layer.

8. The method according to claim 6, wherein the step of removing portions of the pad layer comprises an isotropic etch.

9. The method according to claim 1, wherein the segmentation structures comprise trench capacitors.

10. The method according to claim 1, wherein in said step of forming recessed channel devises said first and a second extension regions serve as a mask.

11. A method for forming a recessed channel transistor and a recessed gate electrode, comprising the steps of:
forming a segment in a semiconductor wafer, said segment being limited on two opposing sides by an isolation trench structure, and on a third and fourth side by a first and second segmentation structure with an upper surface height differing from the wafer surface height;
defining a first and a second extension portion of said active area segment, laterally extending from said third and fourth side into the segment for a predetermined width; and
forming a recessed channel transistor comprising a recessed gate electrode in the remaining portion of the active area segment, wherein between said extension portions a first mask is formed in the active area segment between said extension portions having mask openings corresponding to the extension region,
wherein a second mask is formed in the mask openings of the first mask,
wherein the first mask is removed after formation of the second mask, and
wherein the transistor is formed using the second mask.

12. The method of claim 1, wherein the openings of the first mask correspond to the diameter of said memory cell trench capacitors, and wherein the formation of said extension regions comprises the following steps:
filling said mask openings with a respective infill;
removing said mask; and
forming a respective spacer around said infills.

13. The method of claim 12, wherein said memory cell trench capacitors comprise an inner conductive electrode including a single-sided buried strap for electrical connection to said memory cell transistor forming regions, and wherein said single-sided buried strap is formed by etching back a part of said inner conductive electrode, wherein the formation of said extension regions further comprises the steps of:
forming an insulating liner on said etched back inner conductive electrode before the step of filling said mask openings with a respective infill;
forming a the second mask in said exposed parts of said memory cell transistor forming regions between the spacers;
removing said spacers and said infills;
depositing and planarizing a first insulating layer which forms said extension regions; and
removing said second mask.

14. The method of claim 13, wherein said inner conductive electrodes, said spacers, and said infills are all made of a first conductive material.

15. The method of claim 13, wherein said first conductive material is polysilicon.

16. The method of claim 13, wherein said spacers and said infills are made of carbon.

17. The method of claim 13, wherein said first and second masks are made of silicon nitride.

18. The method of claim 1, wherein a plurality of memory cell trench capacitors is formed using a first mask having openings corresponding to the diameter of said memory cell trench capacitors and formed on said surface, and wherein the formation of said extension regions comprises the following steps:
performing an isotropic etch step in order to remove a part of said first mask such that said first mask only covers the parts of said memory cell transistor forming regions of said predetermined second width to be exposed;
depositing and planarizing a second insulating layer which forms said extension regions; and
removing said first mask.

19. The method of claim 1, wherein said extension regions are formed after the step of forming a plurality of insulation trenches filled with an insulating material as said segmentation structures between said active area lines.

20. The method of claim 19, wherein the formation of said extension regions further comprises the steps of:
filling said mask openings with a respective infill;
recessing said insulating material;
removing said first mask; and
forming a respective spacer around said infills.

21. The method of claim 20, wherein said memory cell trench capacitors comprise a inner conductive electrode including a single-sided buried strap for electrical connection to said memory cell transistor forming regions, and wherein said single-sided buried strap is formed by etching back a part of said inner conductive electrode, wherein the formation of said extension regions further comprises the steps of:
forming an insulating liner on said etched back inner conductive electrode before the step of filling said mask openings with a respective infill;
forming a second mask in said exposed parts of said memory cell transistor forming regions between the spacers;
removing said spacers and said infills;
replacing said etched back part of said inner conductive electrode by an insulating filling;
depositing and planarizing a third insulating layer which forms said extension regions; and
removing said second mask.

22. The method of claim 1, wherein a plurality of memory cell trench capacitors is formed using a first mask having openings corresponding to the diameter of said memory cell trench capacitors and formed on said surface, wherein said extension regions are formed after the step of forming a plurality of insulation trenches filled with an insulating material between said active area lines, and wherein the formation of said extension regions comprises the following steps:
filling said mask openings with a respective infill;
recessing said first mask;
depositing an insulating layer on said recessed first mask;
removing said infills;
etching back said first mask using said insulating layer as a mask;
depositing and planarizing a fourth insulating layer which forms said extension regions; and
removing said first mask.

23. The method of claim 1, wherein a plurality of memory cell trench capacitors is formed using a first mask having openings corresponding to the diameter of said memory cell trench capacitors and formed on said surface, wherein said extension regions are formed after the step of forming a plurality of insulation trenches filled with an insulating material between said active area lines, wherein said memory cell trench capacitors comprise an inner conductive electrode including a single-sided strap for electrical connection to said memory cell transistor forming regions, and wherein said single-sided buried strap is formed by etching back a part of said inner conductive electrode, wherein the formation of said extension regions, and wherein the formation of said extension regions comprises the following steps:
recessing said first mask after forming said single-sided buried strap is formed by etching back a part of said inner conductive electrode;
recessing said insulating material to said upper surface; and
depositing and planarizing a fifth insulating layer which forms said extension regions.

24. The method of claim 1, wherein a plurality of memory cell trench capacitors is formed using a first mask having openings corresponding to the diameter of said memory cell trench capacitors and formed on said surface, wherein said extension regions are formed after the step of forming a plurality of insulation trenches filled with an insulating material between said active area lines, and wherein the formation of said extension regions comprises the following steps:
filling said mask opening with a respective infill;
recessing said first mask;
recessing said said insulating material to the same height as the first mask;
forming a respective spacer around said infills;
etching said first mask to the same height as the upper surface; and
whereby said infills, said remaining first mask; and said spacers form said extension regions.

25. The method of claim 1, wherein a plurality of memory cell trench capacitors is formed using a first mask having openings corresponding to the diameter of said memory cell trench capacitors and formed on said surface, wherein said extension regions are formed after the step of forming a plurality of insulation trenches filled with an insulating material between said active area lines, between said memory cell trench, capacitors comprise an inner conductive electrode including a single-sided buried strap for electrical connection to said memory cell transistor forming regions, and wherein said single-sided buried strap is formed by etching back a part of said inner conductive electrode, wherein the formation of said extension regions, and wherein the formation of said extension regions comprises the following steps:
replacing said etching back a part of said inner conductive electrode by an insulating fill up to the level of said upper surface;
forming a liner on said insulating fill and said mask;
performing an ion implantation step into the horizontal regions of said liner;
selectively removing the unimplanted regions of said liner in an etch step;
recessing said first mask using the remaining regions of said liner as a mask;
removing said liner; and
depositing and planarizing a sixth insulating layer which forms said extension regions.

26. The method of claim 1, wherein a plurality of insulation trenches filled with an insulating material is formed as said segmentation structures between said active area lines.

27. A manufacturing method for an integrated semiconductor memory device comprising the steps of:
providing a semiconductor substrate having an upper surface;
forming a plurality of active area lines in said semiconductor substrate;
forming a plurality of memory cell trench capacitors in said semiconductor substrate along said plurality of active area lines;
said memory cell trench capacitors being separated from each other along said active area lines by intervening respective memory cell transistor forming regions of said semiconductor substrate of a predetermined first width;
providing a fill in said trench capacitors which extends such that it protrudes from said upper surface;
forming a respective extension region above each of the plurality of memory cell trench capacitors on said surface by forming a spacer round said fill, said spacer exposing a part of said memory cell transistor forming regions;
using said extension regions as a mask for etching respective grooves in said exposed parts of said memory cell transistor regions; and
forming a plurality of memory cell transistors, the memory cell transistors comprising recessed gate electrodes, in said grooves.

28. The method of claim 27, wherein a plurality of insulation trenches filled with an insulating material is formed between said active area lines.

29. The method of claim 27, wherein a second mask is formed in the exposed parts of said memory cell transistor farming regions and said fill and spacer are replaced by an insulating as modified extension regions.

30. The method of claim 27, wherein said plurality of memory cell trench capacitors is formed using a first mask having openings corresponding to the diameter of said memory cell french capacitors and formed on said surface.

31. The method of claim 27, wherein said spacers are made of polysilicon.

32. The method of claim 27, wherein said spacers are made of silicon oxide.

33. A self aligned mask structure for manufacturing an integrated semiconductor memory device on a semiconductor substrate, comprising:
a plurality of self-aligned extension regions,
wherein the substrate has an upper surface, a plurality of active area lines formed in the substrate, and a plurality of memory cell trench capacitors formed in the substrate along the plurality of active area lines, the memory cell trench capacitors being separated from each other along the active area lines by intervening respective memory cell transistor forming regions of the substrate, the memory cell transistor forming regions being of a predetermined first width, and
wherein each of the plurality of self-aligned extension regions is above a respective one of the plurality of memory cell trench capacitors on the surface, and wherein the extension regions expose a part of the memory cell transistor forming regions of a predetermined second width.
